(19) United States
(12) Patent Application Publication
(10) Pub. No.: US 2015/0003026 A1
(43) Pub. Date: Jan. 1, 2015

(54) LED LAMP ASSEMBLY AND A CABLE ORGANIZATION DEVICE THEREOF

(71) Applicant: T.Y.C. BROTHER INDUSTRIAL CO., LTD., Tainan City (TW)

(72) Inventors: Min-Feng LIN, Tainan City (TW); Ben THAO, Tainan City (TW)

(73) Assignee: T.Y.C. BROTHER INDUSTRIAL CO., LTD., Tainan City (TW)

(21) Appl. No.: 14/152,328

(22) Filed: Jan. 10, 2014

(30) Foreign Application Priority Data
Jul. 1, 2013 (TW) 102123520

(51) Int. Cl. H05K 7/02

(52) U.S. Cl. CPC H05K 7/02
USPC 361/752

(57) ABSTRACT

An LED lamp assembly includes a base, a circuit board, an LED lamp, a cable, and a cable organization device. The base includes a base body, and a fixed post disposed on the base body. The circuit board is disposed on the base body. The fixed post extends upwardly from the base body. The cable organization device includes a mounting unit connected to the circuit board, and an organization unit connected to the mounting unit. The organization unit includes at least one organization structure, and a retaining groove permitting the fixed post to be inserted thereinto. The organization structure includes a base wall, and first and second clamping walls connected respectively to two opposite ends of the base wall to define a cable clamping groove.

### CROSS-REFERENCE TO RELATED APPLICATION

This application claims priority of Taiwanese Application No. 102123520, filed on Jul. 1, 2013.

### BACKGROUND OF THE INVENTION

1. Field of the Invention

This invention relates to a lamp assembly and a cable organization device thereof, and more particularly to an LED lamp assembly and a cable organization device thereof, which are applicable to a vehicle lamp.

2. Description of the Related Art

Referring to FIGS. 1 and 2, a conventional LED vehicle lamp includes a stepped base 11 having opposite first and second base surfaces 111, 112, and a plurality of mounting holes 113 extending through the first and second base surfaces 111, 112. The LED vehicle lamp further includes a plurality of circuit boards 12 disposed on the first base surface 111 of the base 11, a plurality of cables 13 electrically connected to the circuit boards 12, and a plurality of LED lamps 14 secured respectively to the circuit boards 12. Each circuit board 12 is fastened to the base 11 by two bolts 25. The cables 13 are fastened to the circuit boards 12 by spot welding. The LED lamps 14 extend from the first base surface 111 of the base 11 and through the mounting holes 113, and are exposed from the second base surface 112.

Since the circuit boards 12 are fastened to the base 11 by the bolts 15, and since the cables 13 are fastened to the circuit boards 12 by spot welding, it is troublesome and time-consuming to assemble the base 11, the circuit boards 12, and the cables 13 together. Furthermore, since no means is used to organize the cables 13, entanglement of the cables 13 may occur to result in contact between conductors of the cables 13, which in turn leads to short circuit. In addition, the entangled cables 13 are easy to bend, damage, and break, and thus result in open circuit. To avoid such conditions, the cables 13 can be applied with insulating glue so as to be adhered on the circuit boards 12. However, this also results in a troublesome and time-consuming assembly process.

### SUMMARY OF THE INVENTION

The object of this invention is to provide an LED lamp assembly that is easy and convenient to assemble.

According to an aspect of this invention, there is provided a cable organization device adapted to mounted on a circuit board of an LED lamp assembly, the LED lamp assembly including at least one cable electrically connected to the circuit board, the cable organization device comprising:

a mounting unit adapted to connect with the circuit board; and

an organization unit connected to and disposed above the mounting unit and adapted to be disposed above the circuit board, the organization unit including two organization structures spaced apart from each other, each of the organization structures including a base wall, and first and second clamping walls connected respectively to two opposite ends of the base wall and spaced apart from each other to define a cable clamping groove thereamong, the first clamping walls of the organization structures being spaced apart from and aligned with each other, the second clamping walls of the organization structures being spaced apart from and aligned with each other, the cable clamping grooves in the organization structures being spaced apart from and aligned with each other.

According to another aspect of this invention, there is provided a cable organization device adapted to mounted on a circuit board of an LED lamp assembly, the LED lamp assembly including at least one cable electrically connected to the circuit board, the cable organization device comprising:

a mounting unit adapted to connect with the circuit board; and

an organization unit connected to the mounting unit and including at least one organization structure, the organization structure including a base wall, and first and second clamping walls spaced apart from each other and connected respectively to two opposite ends of the base wall to define a cable clamping groove thereamong.

According to still another aspect of this invention, there is provided a cable organization device adapted to mounted on a circuit board of an LED lamp assembly, the LED lamp assembly including at least one cable electrically connected to the circuit board, and a base, the base including a base body located under the circuit board, and a fixed post extending upwardly from the base body and through the circuit board, the cable organization device comprising:

two organization structures adapted to be disposed between the base body and the circuit board, each of the organization structures including a base wall, and first and second clamping walls extending respectively and downwardly from two opposite ends of the base wall to define a cable clamping groove thereamong, which is adapted to permit the cable to extend therethrough, the first clamping walls of the organization structures being spaced apart from and aligned with each other, the second clamping walls of the organization structures being spaced apart from and aligned with each other, the cable clamping grooves in the organization structures being spaced apart from and aligned with each other; and

a connecting wall connected between top ends of the organization structures and adapted to extend through the circuit board, the connecting wall having a top section disposed at a top end thereof, and two spaced-apart side sections extending respectively and downwardly from two opposite ends of the top section and connected respectively to the second clamping walls of the organization structures, the side sections cooperating with the top section to define a retaining groove that is adapted to permit the fixed post of the base to be inserted thereinto.

According to yet another aspect of this invention, there is provided an LED lamp assembly comprising:

a base including a base body having opposite first and second base surfaces, and a fixed post disposed on the first base surface;

a circuit board disposed on the first base surface, the fixed post of the base extending upwardly from the base body and through the circuit board;

an LED lamp disposed on the circuit board;

a cable electrically connected to the circuit board; and

a cable organization device permitting the cable to extend therethrough and including a mounting unit connected to the circuit board, and an organization unit connected to the mounting unit, the organization unit including at least one organization structure, and a retaining groove permitting the fixed post of the base to be inserted thereinto, the organization structure including a base wall, and first and second clamping walls spaced apart from each other and connected respectively to two opposite ends of the base wall, the base wall cooperating with the first and second clamping walls to define a cable clamping groove thereamong, which permits the cable to extend therethrough.

### BRIEF DESCRIPTION OF THE DRAWINGS

These and other features and advantages of this invention will become apparent in the following detailed description of the preferred embodiments of this invention, with reference to the accompanying drawings, in which:

FIG. 1 is a perspective view of a conventional LED vehicle lamp assembly;

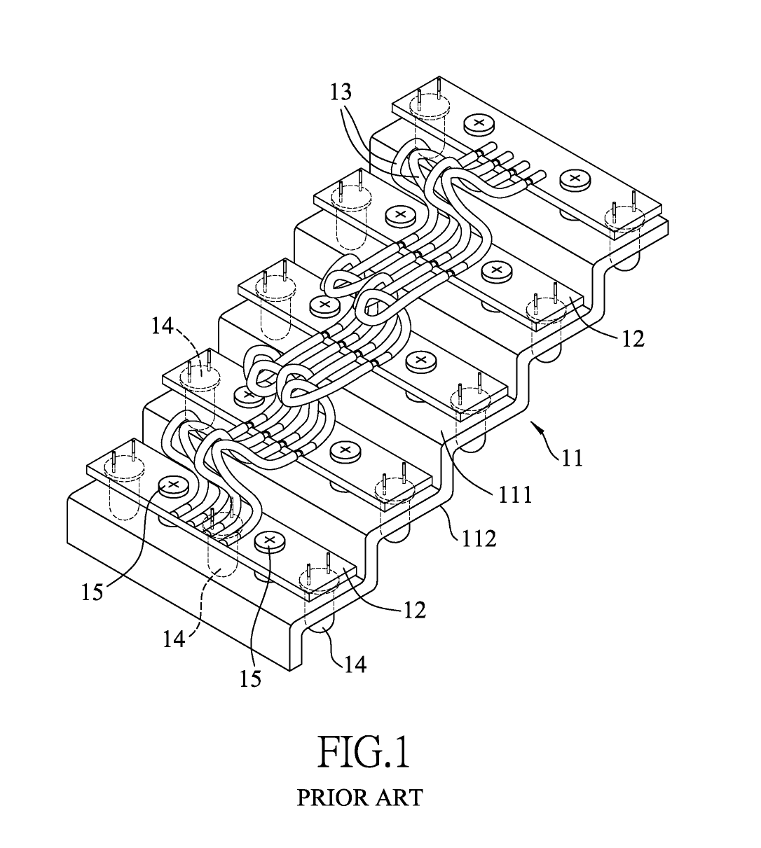

FIG. 2 is a side view of the conventional LED vehicle lamp assembly;

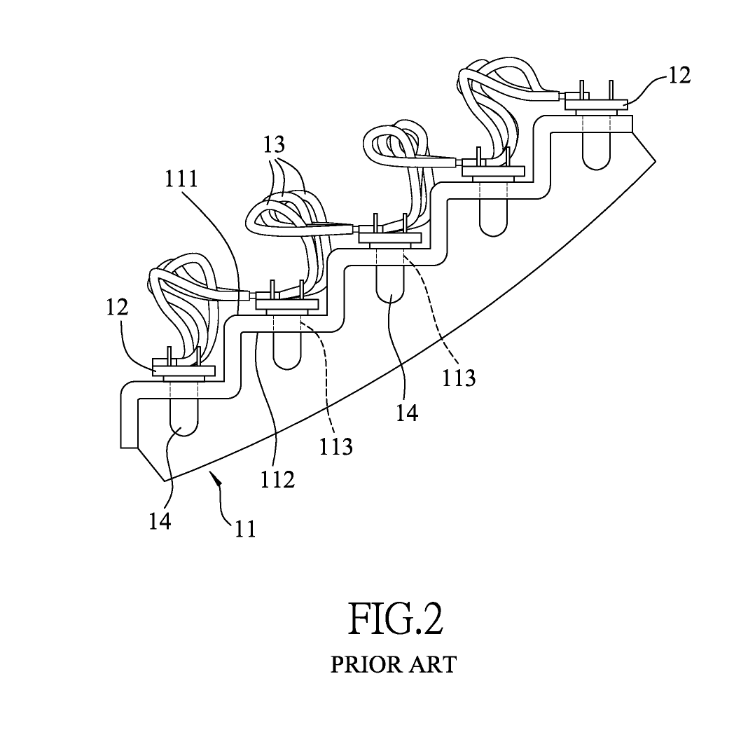

FIG. 3 is an exploded perspective view of the first preferred embodiment of an LED lamp assembly according to this invention;

FIG. 4 is an assembled perspective view of the first preferred embodiment;

FIG. 5 is a front view of the first preferred embodiment;

FIG. 6 is a side view of a cable organization device of the first preferred embodiment;

FIG. 7 is a schematic perspective view illustrating that the first preferred embodiment is applied to a vehicle lamp;

FIG. 8 is an assembled perspective view of the second preferred embodiment of an LED lamp assembly according to this invention;

FIG. 9 is an assembled perspective view of the third preferred embodiment of an LED lamp assembly according to this invention;

FIG. 10 is an exploded perspective view of the fourth preferred embodiment of an LED lamp assembly according to this invention; and

FIG. 11 is a front view of the fourth preferred embodiment.

### DETAILED DESCRIPTION OF THE PREFERRED EMBODIMENTS

Before the present invention is described in greater detail in connection with the preferred embodiments, it should be noted that similar elements and structures are designated by like reference numerals throughout the entire disclosure.

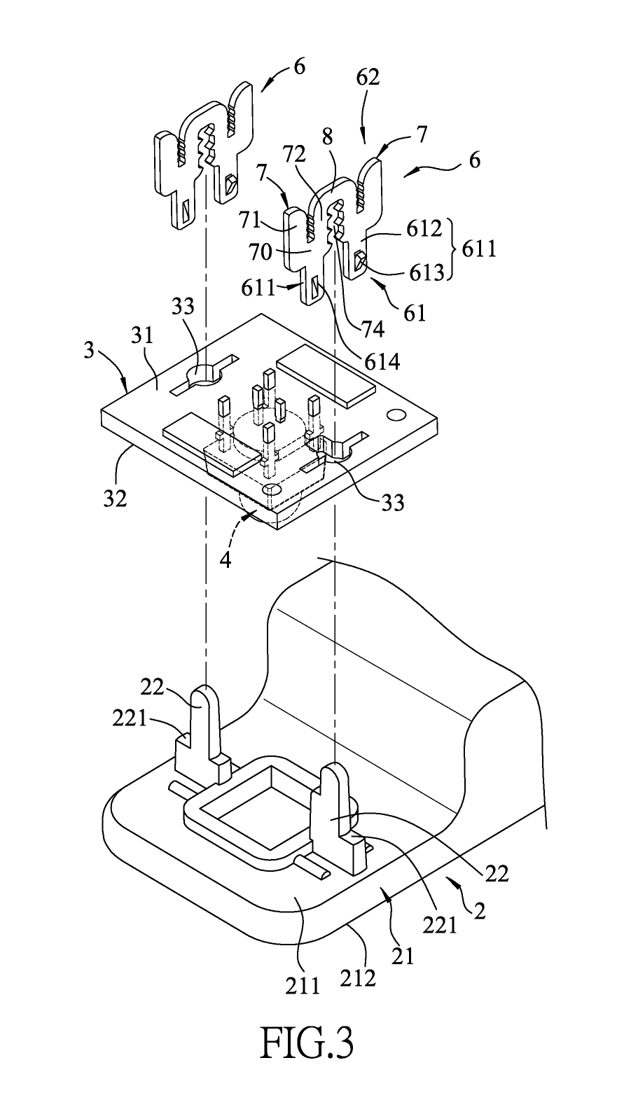

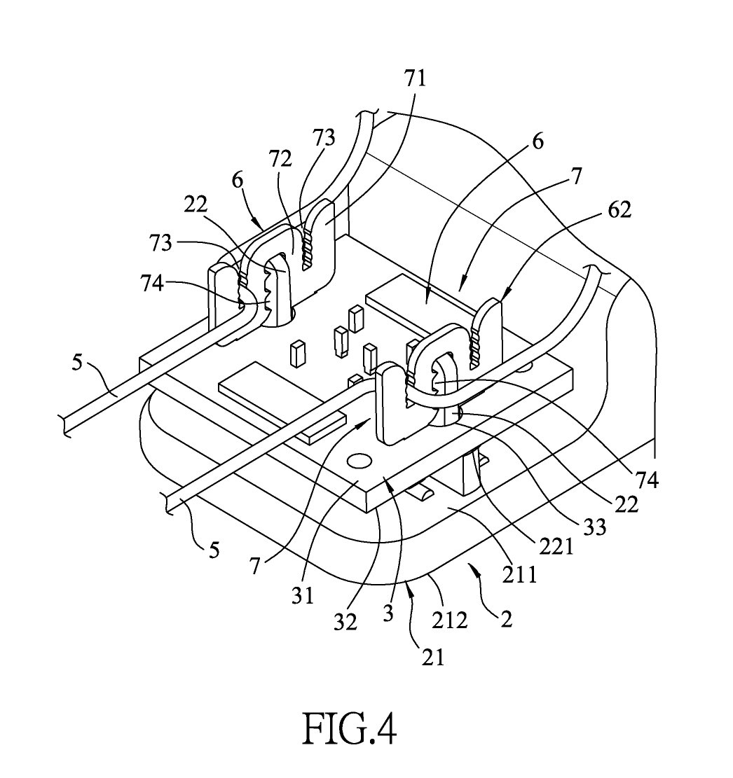

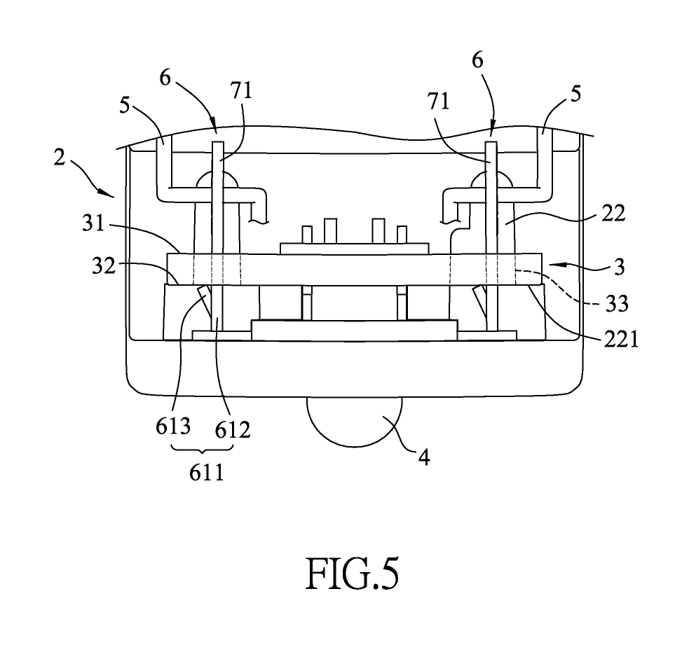

Referring to FIGS. 3, 4, and 5, the first preferred embodiment of an LED lamp assembly according to this invention is applicable to a vehicle lamp, and includes a base 2, a circuit board 3, an LED lamp 4, two cables 5, and two cable organization devices 6.

The base 2 includes a base body 21 having opposite first and second surfaces 211, 212, and two fixed posts 22 disposed on the first base surface 211 and spaced apart from each other along a left-to-right direction. In this embodiment, the first base surface 211 faces upwardly, and the second base surface 212 faces downwardly. The base 2 is made of a light reflective material, so that the second base surface 212 is usable to reflect light emitted by the LED lamp 4. The fixed posts 22 extend upwardly from the first base surface 211. Each fixed post 22 has a width-increased bottom end having an upwardly facing seat surface 221.

The circuit board 3 is disposed on the first base surface 211, and includes an upwardly facing first board surface 31, a second board surface 32 opposite to the first board surface 31 and facing the first base surface 211, and two mounting holes 33 spaced apart from each other along the left-to-right direction and extending through the first and second board surfaces 31, 32. The fixed posts 22 extend respectively through the mounting holes 33, such that the circuit board 3 is seated on the seat surfaces 221 of the fixed posts 22, so as to position the circuit board 3 on the base 2. The base 2 may have additional posts (not shown) for facilitating positioning of the circuit board 3 on the base 2.

The LED lamp 4 is mounted on and electrically connected to the circuit board 3, and extends downwardly from the second base surface 212 of the base 2. In this embodiment, a major portion of light emitted leaves the LED lamp 4 in a downward direction, and the remaining light emitted by the LED lamp 4 leaves laterally the same, and is reflected downwardly by the second base surface 212. It should be noted that, the direction of light emitted by the LED lamp 4 may be changed according to the place at which it is installed, and the orientation in which it is mounted.

The cables 5 are mounted respectively to the cable organization devices 6, and are electrically connected to the circuit board 3. Positive and negative poles of a power supply (not shown) are connected respectively to the cables 5.

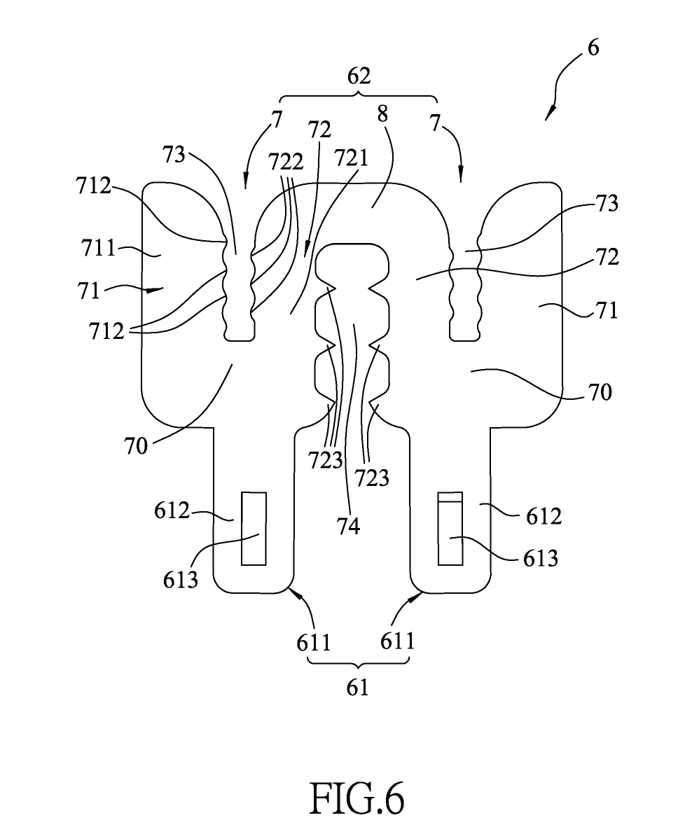

With further reference to FIG. 6, the cable organization devices 6 are spaced apart from each other along the left-to-right direction, and are disposed on the circuit board 3. The cable organization devices 6 are made of copper or a copper alloy, such as phosphor bronze alloy. Such materials have high electric and thermal conductivity, which can facilitate transmission of electrical current in the cables 5 and dissipation of heat. Furthermore, such materials have a high strength, so that the cable organization devices 6 are reinforced.

Each cable organization device 6 includes a mounting unit 61 connected to the circuit board 3, and an organization unit 62 connected to and disposed above the mounting unit 61. Each mounting unit 61 includes two insert walls 611 spaced apart from each other along a front-to-rear direction and inserted into the corresponding mounting hole 33. Each insert wall 611 has an insert wall portion 612 extending through the corresponding mounting hole 33, and a resilient hook wall portion 613 connected to the insert wall portion 612 and abutting against the second board surface 32. As such, a firm connection can be established between the circuit board 3 and the cable organization devices 6.

Each organization unit 62 is disposed above the circuit board 3, and includes two organization structures 7 spaced apart from each other along the front-to-rear direction, and a connecting wall 8 connected between the organization structures 7. The two organization structures 7 are connected respectively to the two insert walls 611 of the corresponding mounting unit 61. Each organization structure 7 includes a base wall 70 connected to the corresponding insert wall 611, and first and second clamping walls 71, 72 connected respectively to and extending upwardly from front and rear ends of the base wall 72 so as to define a cable clamping groove 73 that is opened upwardly and that permits the corresponding cable 5 to extend therethrough.

With particular reference to FIG. 6, each first clamping wall 71 has a first main body 711 and a plurality of first teeth 712 extending from the first main body 711 into the corresponding cable clamping groove 73. Each second clamping wall 72 has a second main body 721, a plurality of second teeth 722 extending from the second main body 721 into the cable clamping groove 73, and a plurality of third teeth 723 extending from the second main body 721 away from the second teeth 722.

One of the cable organization devices 6 will be described in this paragraph. The two second clamping walls 72 are disposed between the two first clamping walls 71. Each connecting wall 8 is connected between top ends of the two second clamping walls 72. The connecting wall 8 cooperates with the second clamping walls 72 to define a retaining groove 74 that permits the corresponding fixed post 22 of the base 2 to extend thereinto. The third teeth 723 extend into the retaining groove 74 to contact the corresponding fixed post 22 so as to position the corresponding fixed post 22 firmly within the retaining groove 74.

With particular reference to FIGS. 3, 4, and 5, during assembly of the LED lamp assembly, the circuit board 3 and the LED lamp 4 are first mounted to the base 2, such that the fixed posts 22 of the base 2 extend through the mounting holes 33 in the circuit board 3 to project from the first board surface 31 of the circuit board 3. Next, the insert walls 611 of the cable organization devices 6 are inserted respectively into the mounting holes 33 in the circuit board 3. During movement of the insert walls 611 in the mounting holes 33, the resilient hook wall portions 613 of the insert walls 611 are pushed by walls of the circuit board 3 defining the mounting holes 33 to retract into holes 614 (see FIG. 3) in the insert wall portions 612. When the resilient hook wall portions 613 pass past the mounting holes 33, their free ends are biased to project from the insert wall portions 612 to contact the second board surface 32 of the circuit board 3, so that removal of the cable organization devices 6 from the circuit board 3 can be prevented. At this time, the organization structures 7 of the cable organization devices 6 are disposed above the first board surface 31 of the circuit board 3.

Subsequently, the cables 5 are inserted respectively through the cable organization devices 6, such that a portion of each cable 5 is pressed downwardly into one of the cable clamping grooves 73 in the corresponding cable organization device 6. During movement of the cables 5 into the cable clamping grooves 73 in the cable organization devices 6, insulating sheaths of the cables 5 are pierced by the first and second teeth 712, 722 such that conductors of the cables 5 are in electrical contact with the cable organization devices 6, respectively, thereby interconnecting electrically the cables 5 and the circuit board 3 through the cable organization devices 6.

It should be noted that, the first teeth 712 are arranged alternately with the second teeth 722. In order words, the first teeth 712 are misaligned from the second teeth 722. As such, the sheaths of the cables 5 can be pierced easily. The number of the cable clamping grooves 73 of each cable organization device 6 is but not limited to two. For example, each cable organization device 6 may be formed with only one cable clamping groove 73.

Due to the presence of the cable organization devices 6, entanglement of the cables 5 can be avoided, and there is not need to weld the cables 5 to the circuit board 3, so as to prevent contact between the conductors of the cables 5, which may result in short circuit, and so as to prevent excessive bending of the cables 5, which may cause the cables 5 to be damaged or broken. Furthermore, the cable organization devices 6 can be assembled to the base 2 and the circuit board 3 by inserting the mounting units 61 through the mounting holes 33 and subsequently inserting the fixed posts 22 into the retaining grooves 74, thereby resulting in a simple and convenient assembly process and a firm connection between the circuit board 3 and the cables 5.

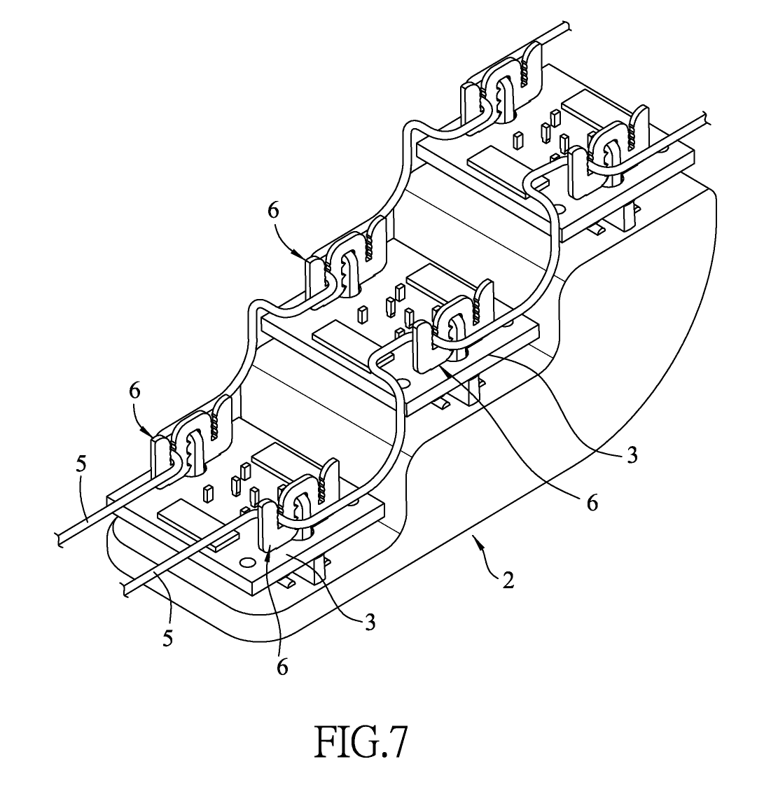

Referring to FIG. 7, if necessary, the base 2 may be designed as a step, which has a plurality of parallel flat surfaces each provided with a circuit board 3, an LED lamp (not shown), and two cable organization devices 6. Two cables 5 extend respectively through the cable organization deices 6 on each flat surface.

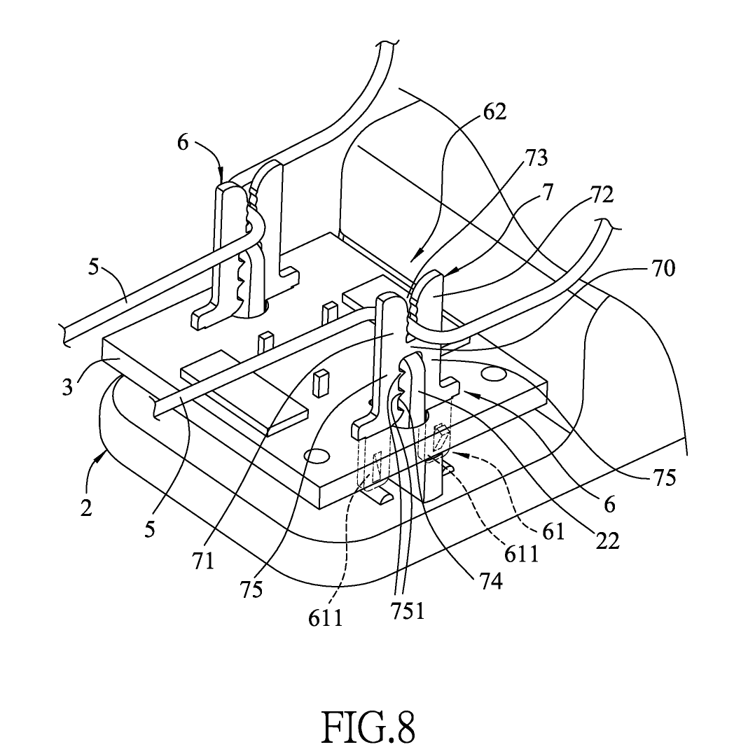

FIG. 8 shows the second preferred embodiment of an LED lamp assembly according to this invention. Unlike the first preferred embodiment, the organization unit 62 of each cable organization device 6 includes only one organization structure 7. In this embodiment, each organization structure 7 further includes two extension walls 75 connected respectively to front and rear ends of the base wall 74 and disposed respectively under the first and second clamping walls 71, 72. The extension walls 75 are connected respectively to the insert walls 611 of the mounting units 61. The two extension walls 75 cooperate with the corresponding base wall 70 to define a retaining groove 74, which permits the corresponding fixed post 22 of the base 2 to extend thereinto. A plurality of teeth 751 are formed on each extension wall 75, and extend into the corresponding retaining groove 74.

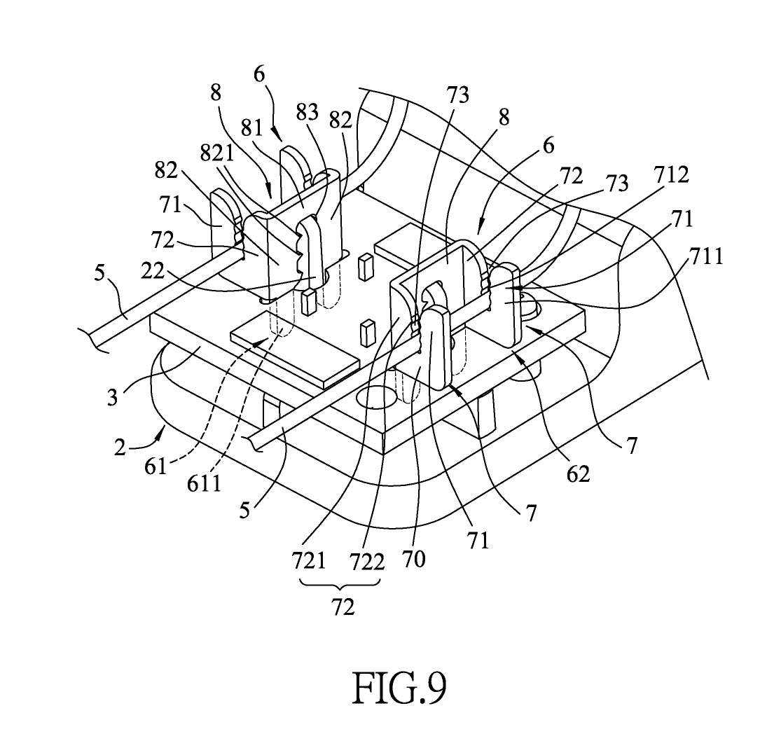

FIG. 9 shows the third preferred embodiment of an LED lamp assembly according to this invention. Unlike the first preferred embodiment, the organization unit 62 of each cable organization device 6 includes two organization structures 7 spaced apart from each other along the front-to-rear direction, and a connecting wall 8 connected between the organization structures 7. The first and second lamping walls 71, 72 of each organization structure 7 are spaced apart from each other along the left-to-right direction. The first clamping walls 71 of the two organization structures 7 are spaced apart from each other along the front-to-rear direction. The two second clamping walls 72 of the two organization structures 7 are spaced apart from each other along the front-to-rear direction. The cable clamping grooves 73 of the two organization structures 7 are spaced apart from each other along the front-to-rear direction. The connecting wall 8 of each cable organization device 6 extends along the front-to-rear direction, and is connected between the two second clamping walls 72. Each connecting wall 8 has a top section 81 located at a top end thereof, and two side sections 82 extending respectively from front and rear ends of the top section 81 to define a retaining groove 83 thereamong, which permits the corresponding fixed post 22 of the base 2 to be inserted thereinto. Each side section has a plurality of teeth 821 extending into the corresponding retaining groove 821.

In this embodiment, the resilient hook wall portions 613 (see FIG. 3) are omitted from the insert walls 611.

In this embodiment, each organization structure 7 is perpendicular to the connecting wall 8, such that the two cable clamping grooves 73 of the two organization structures 7 are arranged along the front-to-rear direction. In this manner, each cable 5 extends through the two cable clamping grooves 73, and a portion thereof extending between the two cable clamping grooves 73 is straight, so that the LED lamp assembly is structurally complete, and connection between the cables 5 and the cable organization devices 6 is firm.

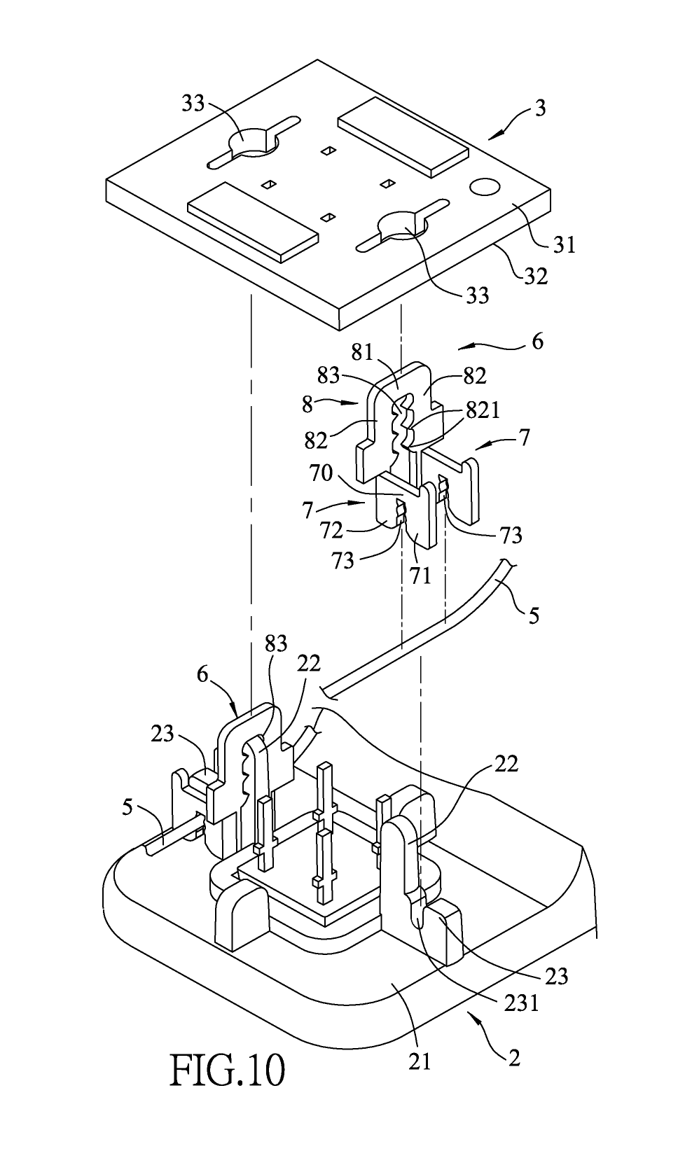

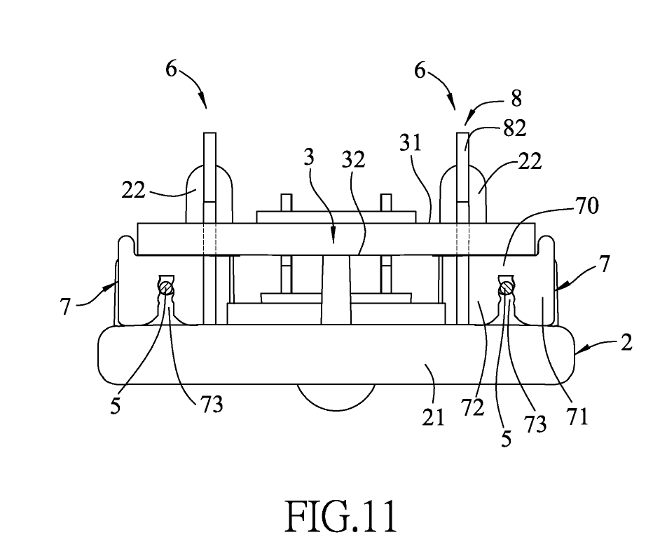

FIGS. 10 and 11 show the fourth preferred embodiment of an LED lamp assembly according to this invention. Unlike the third preferred embodiment, the base 2 further includes two cable supports 23 connected respectively and integrally to lower ends of the fixed posts 22. Each cable support 23 has a top surface formed with a cable receiving slot 231. In this embodiment, the two organization structures 7 of each cable organization device 6 are spaced apart from each other along the front-to-rear direction, and are disposed between the circuit board 3 and the base body 21 of the base 2. The base wall 70 of each organization structure 7 abuts against the second board surface 32 of the circuit board 3. The first and second clamping walls 71, 72 of each organization structure 7 are spaced apart from each other along the left-to-right direction, and extends downwardly from the corresponding base wall 70. Each cable clamping groove 73 is opened downwardly.

The connecting wall 8 of each cable organization device 6 is connected between top ends of the two organization structures 7, and has a top section 81 and two side sections 82 cooperating with the top section 81 to define a retaining groove 83 that permits the corresponding fixed post 22 to be inserted thereinto. The two side sections 82 are connected respectively to top ends of the two second clamping walls 72. Each side section 82 is formed with a plurality of teeth 821 extending into the retaining groove 83.

During assembly, each cable 5 is first inserted through the two cable clamping grooves 73 in the corresponding cable organization device 6. Next, the fixed posts 22 are inserted respectively into the retaining grooves 83 in the cable organization devices 6. At this time, each cable support 23 is disposed between the two organization structures 7 of the corresponding cable organization device 6, such that each cable receiving slot 231 is disposed between and aligned with the cable clamping grooves 73 in the two organization structures 7. Hence, each cable 5 extends through the cable receiving slot 231 in the corresponding cable support 23. Subsequently, the circuit board 3 is sleeved on the cable organization devices 6, in such a manner that the cable organization devices 6 are inserted respectively through the mounting holes 33 in the circuit board 3, thereby completing assembly of LED lamp assembly. At this time, each of the connecting walls 8 of the cable organization devices 6 and the fixed posts 22 of the base 2 is disposed partially above the first board surface 31 of the circuit board 3, and top ends of the first clamping walls 71 of the cable organization devices 6 are disposed above and flank the second board surface 32 of the circuit board 3, thereby facilitating positioning of the circuit board 3.

With this invention thus explained, it is apparent that numerous modifications and variations can be made without departing from the scope and spirit of this invention. It is therefore intended that this invention be limited only as indicated by the appended claims.

We claim:

1. A cable organization device adapted to be mounted on a circuit board of an LED lamp assembly, the LED lamp assembly including at least one cable electrically connected to the circuit board, said cable organization device comprising:
a mounting unit adapted to connect with the circuit board; and
an organization unit connected to and disposed above said mounting unit and adapted to be disposed above the circuit board, said organization unit including two organization structures spaced apart from each other, each of said organization structures including a base wall, and first and second clamping walls connected respectively to two opposite ends of the base wall and spaced apart from each other to define a cable clamping groove thereamong, said first clamping walls of said organization structures being spaced apart from and aligned with each other, said second clamping walls of said organization structures being spaced apart from and aligned with each other, said cable clamping grooves in said organization structures being spaced apart from and aligned with each other.

2. The cable organization device as claimed in claim 1, the LED lamp assembly further including a base that permits the circuit board to be mounted thereon and that includes a fixed post, wherein said cable organization device further comprises a connecting wall connected between said second clamping walls of said organization structures, said connecting wall having a top section located at a top end thereof, and two side sections spaced apart from each other and extending respectively from two opposite ends of said top section to define a retaining groove that is adapted to permit the fixed post of the base to be inserted thereinto.

3. The cable organization device as claimed in claim 2, wherein said first clamping wall of each of said organization structures includes a first main body, and a plurality of first teeth extending from said first main body into said cable clamping groove, said second clamping wall of each of said organization structures including a second main body, and a plurality of second teeth extending from said second main body into said cable clamping groove.

4. The cable organization device as claimed in claim 3, wherein each of said side sections of said connecting wall has a plurality of teeth extending into said retaining groove.

5. The cable organization device as claimed in claim 4, wherein said cable organization device is made of copper or a copper alloy.

6. A cable organization device adapted to mounted on a circuit board of an LED lamp assembly, the LED lamp assembly including at least one cable electrically connected to the circuit board, said cable organization device comprising:
a mounting unit adapted to connect with the circuit board; and
an organization unit connected to said mounting unit and including at least one organization structure, said organization structure including a base wall, and first and second clamping walls spaced apart from each other and connected respectively to two opposite ends of the base wall to define a cable clamping groove thereamong.

7. The cable organization device as claimed in claim 6, wherein said first clamping wall of said organization structure includes a first main body, and a plurality of first teeth extending from said first main body into said cable clamping groove, said second clamping wall of said organization structure including a second main body, and a plurality of second teeth extending from said second main body into said cable clamping groove.

8. The cable organization device as claimed in claim 7, wherein said organization unit includes two said organization units.

9. The cable organization device as claimed in claim 8, the LED lamp assembly further including a base that permits the circuit board to be mounted thereon and that includes a fixed post, wherein said second clamping walls of said organization structures are disposed between said first clamping walls of said organization structures, said organization unit further including a connecting wall connected between said second clamping walls of said organization structure to define a retaining groove thereamong that is adapted to permit the fixed post to be inserted thereinto.

10. The cable organization device as claimed in claim 9, wherein said second clamping wall of each of said organization structure further includes a plurality of third teeth extending from said second main body into said retaining groove.

11. The cable organization device as claimed in claim 10, the circuit board having opposite first and second board surfaces, and a mounting hole extending through the first and second board surfaces, wherein said organization structures are adapted to be disposed on the first board surface, said mounting units including two spaced-apart insert walls connected respectively to said organization units and adapted to be aligned with the mounting hole, each of said insert walls having an insert wall portion adapted to extend from the second board surface through the mounting hole, and a resilient hook wall portion connected to said insert wall portion and adapted to abut against the second board surface.

12. The cable organization device as claimed in claim 6, the LED lamp assembly further including a base permitting the circuit board to be mounted thereto and including a fixed post, wherein said organization structure further includes two extension walls connected respectively to the two opposite ends of said base wall and disposed respectively under said first and second clamping walls, so as to define a retaining groove among said base wall and said extension walls, said retaining groove being adapted to permit the fixed post of the base to be inserted thereinto.

13. A cable organization device adapted to mounted on a circuit board of an LED lamp assembly, the LED lamp assembly including at least one cable electrically connected to the circuit board, and a base, the base including a base body located under the circuit board, and a fixed post extending upwardly from the base body and through the circuit board, said cable organization device comprising:
two organization structures adapted to be disposed between the base body and the circuit board, each of said organization structures including a base wall, and first and second clamping walls extending respectively and downwardly from two opposite ends of said base wall to define a cable clamping groove thereamong, which is adapted to permit the cable to extend therethrough, said first clamping walls of said organization structures being spaced apart from and aligned with each other, said second clamping walls of said organization structures being spaced apart from and aligned with each other, said cable clamping grooves in said organization structures being spaced apart from and aligned with each other; and
a connecting wall connected between top ends of said organization structures and adapted to extend through the circuit board, said connecting wall having a top section disposed at a top end thereof, and two spaced-apart side sections extending respectively and downwardly from two opposite ends of said top section and connected respectively to said second clamping walls of said organization structures, said side sections cooperating with said top section to define a retaining groove that is adapted to permit said fixed post of said base to be inserted thereinto.

14. An LED lamp assembly comprising:
a base including a base body having opposite first and second base surfaces, and a fixed post extending upwardly from said first base surface;
a circuit board disposed on said first base surface, said fixed post of said base extending through said circuit board;
an LED lamp disposed on said circuit board;
a cable electrically connected to said circuit board; and
a cable organization device permitting said cable to extend therethrough and including a mounting unit connected to said circuit board, and an organization unit connected to said mounting unit, said organization unit including at least one organization structure, and a retaining groove permitting said fixed post of said base to be inserted thereinto, said organization structure including a base wall, and first and second clamping walls spaced apart from each other and connected respectively to two opposite ends of said base wall, said base wall cooperating with said first and second clamping walls to define a cable clamping groove thereamong, which permits said cable to extend therethrough.
